(19) United States
(12) Patent Application Publication
(10) Pub. No.: US 2004/0166445 A1
(43) Pub. Date: Aug. 26, 2004

(54) Method and apparatus for forming damascene structure, and damascene structure

(76) Inventors: Tetsunori Kaji, Tokuyama (JP); Yoichi Uchimaki, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/787,460

(22) Filed: Feb. 27, 2004

Related U.S. Application Data
(62) Division of application No. 10/365,642, filed on Feb. 13, 2003.

(30) Foreign Application Priority Data
Sep. 12, 2002 (JP) 2002-266371

(51) Int. Cl. G03F 7/00

(52) U.S. Cl. 430/314; 430/313; 430/311

(57) ABSTRACT

An apparatus for creating a conductive damascene by filling copper in a plug portion formed on an insulating film, the apparatus comprising an etching chamber 151A for etching a low-k material, a vacuum transfer chamber 153 for transferring in vacuum a sample being etched, a receiving means for receiving the transferred sample, a voltage application means, a copper barrier processing chamber 151B for performing a copper barrier process by reforming the surface of the sample through carbonizing process, nitriding process, brominating process, boride-forming process, reduction process, amorphous-forming process or a combination thereof, which is realized by making ions accelerated by voltage or neutral particles obtained by diselectrifying the accelerated ions collide against the etched surface, and a high vacuum processing chamber 151C where copper is filled in the plug portion having the etched surface with a copper barrier.

### FIELD OF THE INVENTION

The present invention relates to the method and apparatus for providing a damascene process to a sample such as a semiconductor or a liquid crystal, and a damascene structure formed thereby, and especially relates to the method and apparatus for forming a damascene structure suitable for realizing a multilevel interconnection.

### DESCRIPTION OF THE RELATED ART

The design rule of semiconductor integrated circuits is expected to reduce size in the near future to 0.1 μm and smaller. One of the largest drawbacks in improving the speed of the circuit performance is the delay of signals due to wiring. In order to solve this problem and to reduce the capacity between wires and reduce wiring resistance, there are attempts to realize multilevel interconnection by a dual damascene process or a single damascene process, filling copper (being a conductive material with low resistivity) in a low-k material (relative permittivity being 3.0 or smaller, preferably 2.5 or smaller) (refer for example to patent document 1 and patent document 2 ).

An example of the dual damascene process is illustrated in FIGS. 10A through 10L, and FIGS. 11M through 11P. The dual damascene process comprises for example the following steps.

FIG. 10A: Embedding a lower layer wiring 101 in a first insulating film 100, and forming an insulating film 102 over the lower layer wiring as etch stopper (step A).

FIG. 10B: Forming a second insulating film 103 on the insulating film 102 over the lower layer wiring (step B).

FIG. 10C: Forming a third insulating film 104 as etch stopper on the second insulating film 103 (step C).

FIG. 10D: After forming a photoresist layer 105 on the third insulating film 104, forming a first mask opening 106 on the photoresist layer 105 by photolithography technique (step D). The first mask opening 106 corresponds to the dimension of a plug portion 112 explained later.

FIG. 10E: Using the photoresist layer 105 as mask, performing etching to create a first opening 107 on the third insulating film 104 (step E).

FIG. 10F: Forming a fourth insulating film 108 on the third insulating film 104 and on the second insulating film 103 corresponding to the first opening 107 (step F).

FIG. 10G: Forming a photoresist layer 109 on the fourth insulating film 108, and creating a second mask opening 110 on the photoresist layer 109 by photolithography technique (step G). The second mask opening 110 corresponds to the dimension of a trench portion 113 explained later.

FIG. 10H: Forming a second opening 111 on the fourth insulating film 108 by etching the fourth insulating film 108 using the photoresist layer 110 as mask (step H).

FIG. 10I: Etching the second insulating film 103 to a determined depth utilizing the patterned third insulating film 104 as mask (step I).

FIG. 10J: Etching the third insulating film 104 utilizing the patterned fourth insulating film 108 as mask (step J).

FIG. 10K: Further etching the second insulating film 103 utilizing the fourth insulating film 108 and third insulating film 104 as mask (step K) . At this time, the etching of the plug portion 112 is advanced, so that the trench portion 113 and plug portion 112 are created.

FIG. 10L: Etching the insulating film 102 under the plug portion 112 utilizing the plug portion 112 as mask, thus forming a third opening 116 on the insulating film 102 (step L).

FIG. 11M: Forming a barrier metal layer 114 with a thickness of 20 to 50 nm on the exposed surface of the sample, including trench portion 113, plug portion 112, inner wall of third opening 116, surface of lower layer wiring 101 under third opening, and surface of fourth insulating film 108 (step M).

FIG. 11N: Depositing a seed layer of copper as conductive material on the barrier metal layer 114, then filling copper 115 in the trench portion 113 and plug portion 112 (step N).

FIG. 11P: Smoothing the surface of the copper thin film (conductive material 115) by CMP (chemical-mechanical polishing) (step P).

The first insulating film 100 and the second insulating film 103 are formed of a low-k material (having a relative permittivity of 3.0 or smaller, preferably 2.5 or smaller), and the insulating film 102, the third insulating film 104 and the fourth insulating film 108 are formed for example of SiN or SiC having a function to prevent etching. Currently, the barrier layer 114 is mainly formed of metals such as TiN that prevents diffusion of the conductive material 115 component into the low-k material and prevents diffusion of oxygen and fluorine components etc. from the low-k material to the conductive material. Further, a process that enables the fourth insulating film 108 to be omitted has been reported.

The steps shown through FIG. 10B to the former half of FIG. 10D are performed by a film forming apparatus (sputtering apparatus, CVD apparatus, etc.). The latter half of step D is performed by a lithography apparatus. Step E is performed by an etching apparatus. Steps F through former half of G are performed by a film forming apparatus. The latter half of step G is performed by a lithography apparatus. Steps H through L are performed by an etching apparatus. Step M is performed by a film forming apparatus. Step N is performed either by a film forming or metal plating apparatus. Step P is performed by a CMP apparatus.

In FIGS. 10 and 11, a portion of the detailed processes such as cleaning and ashing of the photoresist is omitted. Various other possible processes exist in filling copper as wiring material to a sample according to the single and dual damascene processes, but as for the barrier against copper, it is common to create a barrier metal layer such as TiN on the surface after forming trenches and plugs, and then filling the copper above the barrier metal layer (refer for example to patent documents 3, 4 and 5).

According to the prior art disclosed for example in the above patent documents, a barrier metal layer (currently having a thickness between 30 and 100 nm) having a higher specific resistance compared to copper is formed on the whole surface of the sample including the bottom and side walls of the trench portions 113 and plug portions 112. Therefore, in the trench portions 113 and plug portions 112, the trench width or plug diameter for the copper filling (conductive material portion) having a low specific resistance is reduced by the thickness of the barrier metal layer 114 deposited on the side walls defining these portions, thus causing drawback of increased wiring resistance. Furthermore, since the barrier metal layer 114 on the bottom surface of the plug portion having higher resistance than copper is inserted between the lower layer copper wiring (corresponding to 101 of FIG. 11) and the copper wiring there above (corresponding to 115 of FIG. 11), the contact resistance between the upper and lower copper wiring layers increase undesirably.

In the years 2010 and 2016, it is predicted that the design rules of the IC will become 45 nm and 22 nm, respectively, along with which the trench width and plug diameter must be reduced to 100 nm or smaller, and 50 nm or smaller, respectively. Since the barrier metal layer must be formed on the whole surface of the IC including the walls of the trench and plug, the miniaturization of the parts causes the influence of wiring resistance caused by the barrier metal layer to become significant, leading to a serious degradation of the IC performance. It is predicted that in 2010 and 2016, the thickness of the barrier metal layer is reduced to 5 nm and 2.5 nm, respectively, but considering the current condition that the dispersion of copper to the low-k material increases greatly when the barrier metal layer thickness is reduced to about 20 nm or less, we must say that the achievement of the above goal is very challenging.

It is known that a two layer structure can be created by forming on an ordinary flat low-k material film a flat SiC film having a thickness of 80 nm functioning as a barrier and with a value of k being 5.5 or less, and while depositing the flat SiC film, processing the film by plasma using rare gas or nitrogen-containing gas at 0.1 to 25 Torr, in order to create a film whose function to prevent dispersion of oxygen is improved (refer for example to patent document 6). However, there is no description related to etching the trench portions and plug portions in a single or dual damascene process after forming the film, or to processing the material after the trench portions and plug portions are formed.

Further, there is a proposal of a method according to which after forming the trench portions and the plug portions of the dual damascene structure, plasma is generated by a pressure of 1 mTorr to 50 mTorr (0.133 Pa to 6.6 Pa) utilizing gases such as N₂, NH₃ etc. and utilizing an RF/microwave power supply of 100 W to 2 kW to perform an isotropic/anisotropic plasma process, thus forming by chemical reaction a “pseudo-carbon nitride layer” on the side walls of the trench portions and plug portions of the dual damascene structure in the low-k material composed of fluoride dielectric, providing a barrier property against copper. The proposed method further discloses forming a normal metal barrier layer on the “pseudo-carbon nitride layer”, then inlaying copper on the structure (refer for example to patent document 7).

However, it is difficult to sufficiently reform the surface of the low-k material merely by performing the plasma process in a pressure of 1 mTorr to 50 mTorr, so according to the proposed method, the degree of reform is insufficient and the depth of the reform is as shallow as 1 nm or less. Especially, the accelerated ions rarely reach the side walls of the trenches and plugs, and only the uncharged atoms/molecules adhere thereto by dispersion, so as shown in FIG. 4a, only incomplete reaction occurs on the surface layer (1 nm or less) of the side walls.

Moreover, it is known that in order to reform an SiO₂ film into SiN by nitrogen plasma to a depth of 0.5 nm, it takes about 300 seconds (refer for example to patent document 8). Therefore, the barrier against copper is insufficient by this reform alone, so a barrier metal layer must further be added, thus suffering the same drawback as the prior art method utilizing the barrier metal layer.

There has been attempts to provide a barrier property to the low-k material itself, but since such property degrades the permittivity, the density of the low-k material and thus the coupling between atoms tend to drop. Therefore, it is extremely difficult to provide a complete barrier property to the low-k material preventing dispersion of oxygen/fluorine and the like.

Furthermore, since according to the prior art the substrate is subjected to treatment in an etching apparatus forming trenches and/or plug portions to the low-k material (having a relative permittivity of 3.0 or below, preferably 2.5 or below), before being transferred in atmospheric pressure having moisture to a film forming apparatus, the trench portion sand plug portions being etched were undesirably degraded.

According to the prior art, there were no considerations on producing a highly reliable multilevel interconnection utilizing the low-k material, and the yield factor was unsatisfactory, increasing the manufacture cost.

List of Patent Documents:

Patent document 1 : U.S. Pat. No. 6,365,506

Patent document 2 : Pamphlet of International Publication No. 01/99182

Patent document 3: U.S. Pat. No. 6,100,184

Patent document 4: Japanese Patent Laid-Open Publication No. 2000-232106

Patent document 5: U.S. Pat. No. 6,344,693

Patent document 6: U.S. Pat. No. 2002/16085

Patent document 7: U.S. Pat. No. 2002/0001952

Patent document 8: Japanese Patent Laid-Open Publication No. 2001-291866

### SUMMARY OF THE INVENTION

The object of the present invention is to maintain a low wiring resistance in a miniaturized IC structure so as to advance the performance of the IC and to improve the productivity of the multilevel interconnection.

The low-k material includes inorganic SOG (spin-on glass), organic SOG, organic polymer, porous material, material to be deposited by CVD (such as Si-C), and other dielectric material having a permittivity of 3 or less (preferably 2.5 or less).

In order to achieve this object, the present invention processes a sample including a low-k material in an etching apparatus (into the state of step K of FIG. 10), then within the same apparatus, without exposing the sample to atmospheric pressure, either in the same processing chamber or in a different chamber after transferring the sample in vacuum, provides a barrier treatment to the sample by reforming the surface of the sample by accelerating ions and particles by a voltage of 1 kV to 50 kV (preferably 2 kV to 20 kV) and making them collide against the exposed surface of the etched low-k material, the reforming process performed so as to carbonize, nitride, bromize, form into boride, reduce, or form into amorphous, or a combination thereof, the surface of the low-k material.

Moreover, by depositing a surface reforming material to the exposed surface of the low-k material at the time of or before the collision of the accelerated ions and particles against the sample, the mutual reaction between the deposited material and the collision of the accelerated ions/particles further accelerate the surface reforming process performed so as to carbonize, nitride, bromize, form into boride, reduce, or form into amorphous, or a combination thereof, the surface of the low-k material.

In other words, by the collision of accelerated ions/particles, the ions/particles themselves or the material or the low-k material existing in the portion on which the ions/particles collide against are implanted to a depth of 3 nm to 50 nm (preferably 5 nm to 30 nm) from the surface of the low-k material. Further, the collision energy of the accelerated ions and particles generate heat locally, the heat greatly accelerating the coupling between the implanted particles and low-k material, between the implanted particles themselves, and between the low-k materials, advancing the barrier treatment performed so as to carbonize, nitride, bromize, formin to boride, reduce, or form into amorphous, or a combination thereof, the surface of the low-k material.

According to the present invention, the implanted ions/particles include carbon, nitrogen, boron, bromine, silicon, hydrogen, oxygen, compounds including the listed, ions thereof, rare gas, and ions of the rare gas.

In summary, according to the relation between the energy of the particles and the implanting depth of the particles to the low-k material as shown in FIG. 12, the implanting depth of the particles increases as the particle energy increases (the implanting depth is illustrated so that the implanted particle concentration is 1/e; e=2.718; of the peak concentration) . The implanted depth is within a certain range according to the material of the sample and the particles being implanted. The applicable range of the present invention is 1 kV to 50 kV (preferably 2 kV to 20 kV) in acceleration voltage. Since the particle acceleration/collision chamber is small, the particle acceleration voltage is set below 50 kV (preferably below 20 kV), so that the barrier treatment or protection treatment is performed by a desired surface reform process with the accelerated particles implanted to a depth of 3 nm to 50 nm (preferably 5 nm to 30 nm).

In order to execute the above process, the accelerated particles are made to collide against the trench portions and plug portions (including side walls) of the single or dual damascene structure formed to the sample, and the sample surface is heated to 250-450 degrees, thus accelerating the reformation of the surface.

By connecting a biasing high frequency or pulse power supply to the sample stage in an ordinary plasma process where the pressure is between 0.1 mTorr to 25 mTorr, high energy ion radiation becomes possible. However, by the property of the ions to move straight within a plasma sheath, it is difficult to irradiate high energy ions to the vertical wall portions of the sample. The present invention solves this problem by methods 1, 2 and 3 explained below.

(1) The mean free path of argon and nitrogen ions in 1 atm is approximately 60 nm, which is substantially equal to or smaller than the plug diameter. When the pressure increases to 2-10 atm, the mean free path of the ions become sufficiently smaller than the plug diameter. Thus, by increasing the plasma processing pressure close to atmospheric pressure or few times greater than atmospheric pressure, the mean free path of the ions and the plasma sheath width become smaller than the trench width or plug diameter, enabling the plasma to reach the trenches and plugs. By adding a bias power to the sample, the ions accelerated by a voltage of 1 kV to 50 kV (preferably 2 kV to 20 kV) can be irradiated to the whole surface of the sample including the vertical wall portions.

(2) The ion beam including an oblique angle component output from a large-area ion source having an area equal to or larger than ¼ the sample area and accelerated by 1 kV to 50 kV (preferably 2 kV to 20 kV) is taken out after neutralization if necessary, and irradiated onto the sample. It is best that significant collision does not occur between the accelerated particle takeout portion and the sample. The process is performed in vacuum atmosphere of approximately 3×10⁻² Pa or lower. The processing chamber can be miniaturized, and can be handled as one processing chamber included in a multi-chamber system.

(3) The sample is placed in a high vacuum atmosphere of 10⁻⁶ Pa or lower, and the ions generated by a plasma source are accelerated by a voltage of 1 kV to 50 kV (preferably 2 kV to 20 kV), and then the desirable ion is subjected to mass separation/neutralization if necessary, before the accelerated particles are irradiated to the sample from an oblique direction. By rotating and/or moving the sample, the accelerated particles can be irradiated from an oblique direction onto the whole sample surface including the side walls of the trenches and plug holes. Further, the use of a single wafer ion injection apparatus omitting a mass separation unit enables the processing chamber to be miniaturized, making it easier for the chamber to be included in the multi-chamber system.

Regarding improvement of the CVD process utilizing an accelerated particle beam, U.S. Pat. No. 2001/0055649 discloses a process utilizing an apparatus similar to the one explained in method (2), but according to the disclosure, a barrier metal layer such as TiN is deposited as in the prior art on the surface after trenches and plug holes are formed. The improvement taught in the disclosure related to the use of the accelerated particle beam is aimed at improving the adhesion between the base insulating layer and the barrier metal layer, and offers a totally different object, effect and embodiment from the present invention.

Moreover, providing a barrier property to the low-k material by the accelerated particles causes the permittivity of the low-k surface to be somewhat increased, but the ratio of the surface portion (3-50 nm) to the whole low-k layer is very small, so the increase of permittivity in the surface of the low-k layer does not cause the inter-wire capacity of the IC to increase significantly.

In the preferred embodiment of the present invention, copper is utilized as the conductive material, but the conductive material or the damascene structure to which the present invention can be applied is not limited to such embodiment. The present invention can be applied to any possible example where the dispersion of substance between the conductive material and the insulating film causes degradation of performance.

### BRIEF DESCRIPTION OF THE DRAWINGS

FIG. 1 shows an example of the multi-chamber apparatus applicable to the present invention;

FIG. 2 shows an example of the surface reforming chamber according to the present invention;

FIG. 3 shows an example of a surface reforming process sequence of the present invention;

FIG. 4 shows the comparison between the prior art example and the present invention of the atom arrangement of the low-k material near the exposed surface;

FIG. 5 is a view explaining the hardness (relative value) of the insulator with C—H coupling and C—F coupling against the fluorine content rate, and the relative insulator thickness from the surface in contact with copper to the portion where copper concentration becomes 1/10000;

FIG. 6 shows an example of the driven state of FIG. 2;

FIG. 7 shows another embodiment of the present invention utilizing a large-area accelerated beam processing chamber;

FIG. 8 shows another embodiment of the present invention where the sample is placed under high vacuum atmosphere;

FIG. 9 shows another example of the multi-chamber apparatus applicable to the present invention;

FIG. 10 shows a portion of the drawing explaining the damascene processes of the prior art;

FIG. 11 shows the remaining portion of the drawing explaining the damascene processes of the prior art; and

FIG. 12 shows the outline of the relationship between the particle acceleration energy and the particle penetration depth, and the area of application of the present invention.

### DETAILED DESCRIPTION OF THE PREFERRED EMBODIMENTS

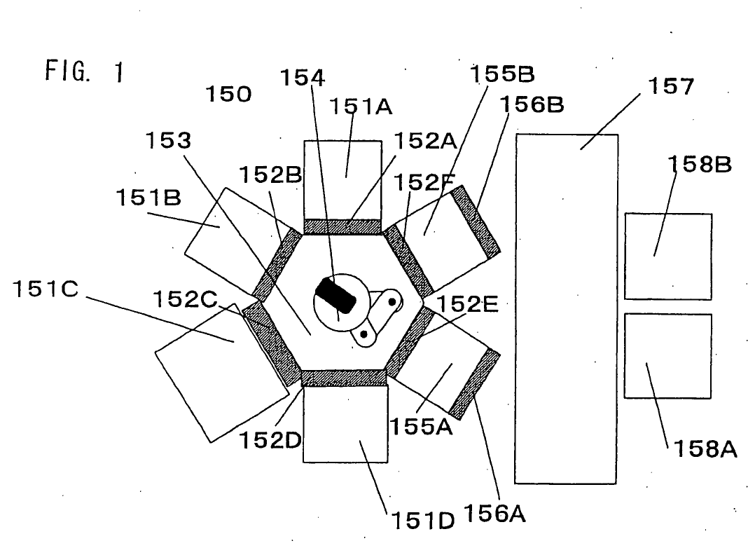

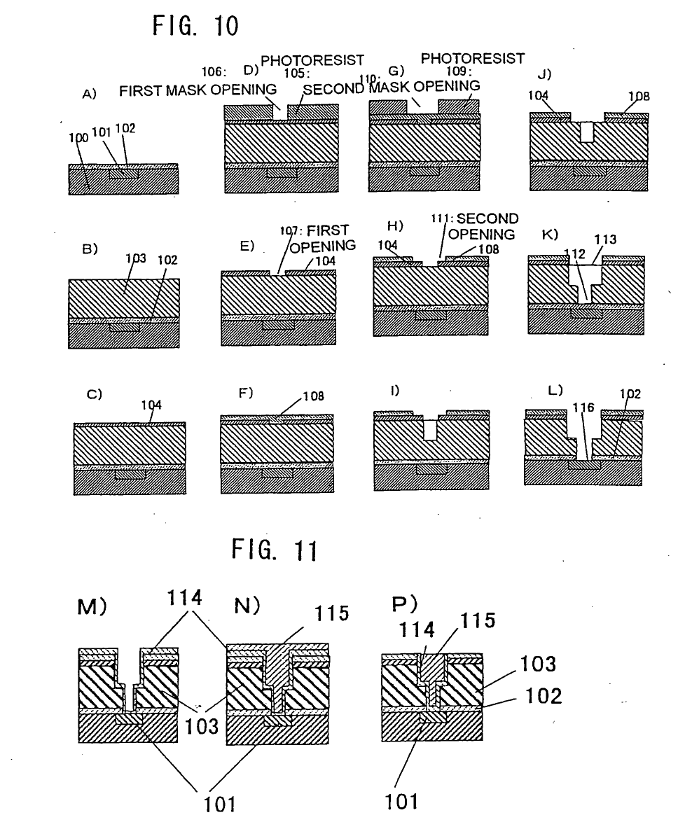

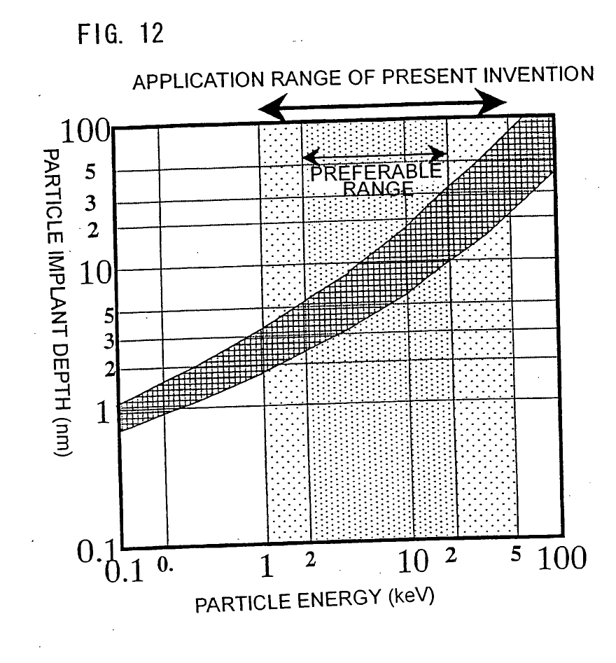

The preferred embodiment of the present invention will now be explained with reference to FIGS. 1, 2, 3 and 6. FIG. 1 shows one arrangement of the apparatus for a damascene process according to the present invention. A damascene process apparatus 1 according to the present invention comprises a vacuum transfer chamber 153 surrounded by plural processing chambers 151A-151D via plural gate valves 152A-152D. At least one of the processing chambers (for example, 151A) is an etching chamber, and performs at least the etching processes shown in FIG. 10 as FIGS. 10I, 10J and 10L. At least another one of the processing chambers (for example, 151B) is a particle acceleration/collision chamber, and a sample is transferred in vacuum environment between the etching chamber 151A and the particle acceleration/collision chamber 151B via the vacuum transfer chamber 153.

Samples are stored in plural mini-environment corresponding FOUPs (front opening unified pods) 158A, 158B positioned in atmospheric pressure, and the samples are taken out by an atmospheric robot 157 positioned in clean atmospheric pressure environment and introduced into plural lock chambers 155A, 155B. Each lock chamber 155A, 155B provides buffering between atmosphere and vacuum. After the sample(s) is/are introduced into lock chambers 155A and/or 155B, the atmosphere-side gate valves 156A and/or 156B is/are closed, and the lock chamber(s) is/are evacuated by a vacuum pump connected thereto. After the pressure within the chamber has reduced to below a predetermined pressure, the vacuum-side gate valve 152E and/or 152F is/are opened, and the sample(s) is/are taken out by a vacuum robot 154 installed within the vacuum transfer chamber 153, and the gate valve (for example, 152A) of a desired processing chamber (for example, 151A) is opened to place the sample on a sample stage 6 (not shown) within the processing chamber, before the gate valve 152A of the chamber is closed and the processing of the sample is started.

After the process within processing chamber 151A is completed, the gate valve 152A of chamber 151A is reopened to take out the sample by the vacuum robot 154 and to transfer the sample to the next desired processing chamber (for example, 151B) When all the processes are completed, the sample is returned to the plural FOUPS 158 through the opposite route as when the sample was introduced.

The configuration of the apparatus according to the invention is not limited to the one illustrated in FIG. 1, but can be, for example, an apparatus where plural processing chambers are aligned along a common linear vacuum transfer path via gate valves (if necessary, with transfer apparatuses dedicated to individual processing chambers).

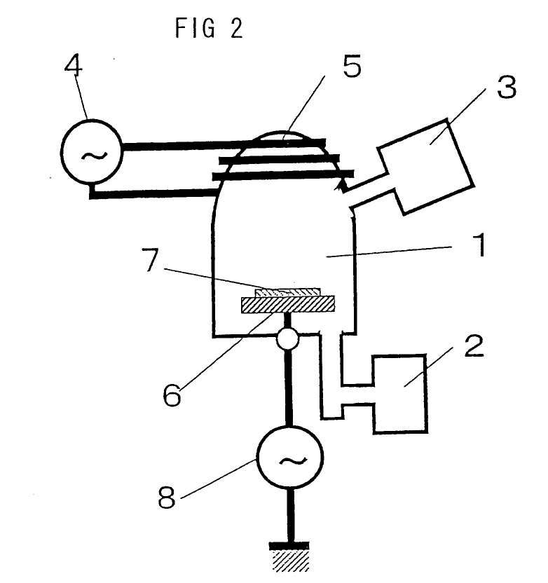

FIG. 2 is referred to in explaining the structure of a surface reforming chamber. A surface reforming chamber 1 comprises an evacuation apparatus 2, a gas source 3, an RF power supply 4 for plasma generation, a coil antenna 5, a stage 6, and an RF power supply 8 for bias application. A sample 7 is mounted on the stage 6.

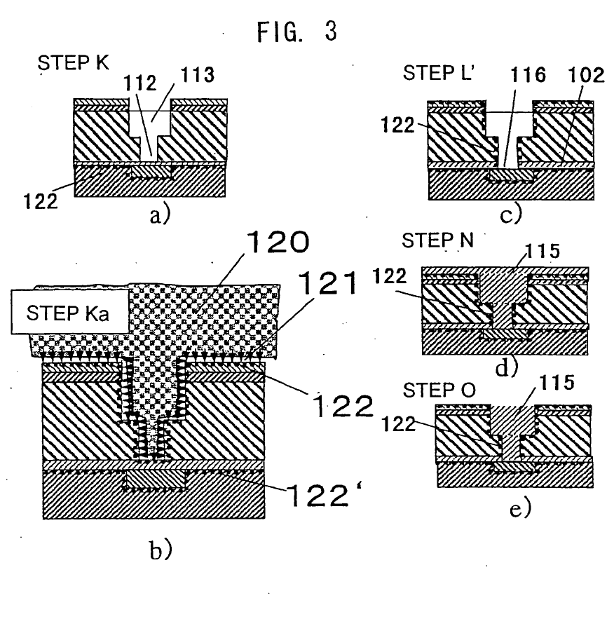

The sample 7 having a low-k material etched within one of the etching chambers (for example, 151A) of the processing chambers 151 is transferred via vacuum transfer chamber 153 into the surface reforming chamber 1 (for example, 151B) illustrated in FIG. 2 which is another processing chamber of the chambers 151, and mounted on stage 6. At this time, as shown in FIG. 3a (step K), the cross-section of the sample is similar to that shown in the prior art example FIG. 10K (step K) . The surface reforming process corresponding to FIG. 3b mentioned hereafter (step Ka) is performed “during creation of a trench for filling in a lower layer wiring 101 in a first insulation layer 100” of FIG. 10A, and a barrier layer 122′ is created in the first insulation film 100 adjacent to the lower layer wiring 101.

The inside of the surface reforming chamber 1 is evacuated by the evacuation apparatus 2 to vacuum state, then a predetermined gas is introduced from a gas source 3 with a predetermined flow rate via a flow controller (not shown), and the evacuation speed is adjusted so that the pressure within surface reforming chamber 1 falls within a predetermined range of 1 hpa to 10 hpa.

In order to carbonize the trench or plug portion surface of the low-k material created by the former etching process so as to provide a barrier, a mixed gas formed of rare gas such as helium or argon and hydrocarbon gas including much carbon (for example, methane or acetylene) is used as gas. Thereafter, the RF power supply 4 for generating plasma having a frequency range of 10 MHz to 10 MHz is switched on to provide high frequency power into the chamber 1 via the coil antenna 5 to turn the gas therein into plasma.

The RF power supply 8 for bias application with a frequency range of 0.1 MHz to 20 MHz, lower than that of the plasma generating RF power source 4, is connected to the stage 6, so as to control the acceleration energy of the ions introduced to the exposed surface of the sample 7 on the stage 6 to within 1 kV-50 kV (preferably within 2 kV-20 kV). Further, a matching box is provided between the output of plasma generating RF power supply 4 or bias applying power supply 8 and each load (not shown in FIG. 2). A direct-current blocking capacitance is installed in each matching box.

The cross-section of the sample during the plasma process (step Ka) is shown in FIG. 3b. Since the processing pressure is high, the plasma 120 is introduced even into the plug portions 112 and trench portions 113 having a diameter smaller than 100 nm. On the whole exposed surface of the sample including the side and bottom walls of the trench 113 and plug 112, the exposed surface of the insulating film 102 above the lower layer wiring and the surface of the fourth insulating film 108 is created a sheath of few nm to a few dozen nm between the plasma 120. The ions 121 of rare gas/carbon/hydrocarbon generated within the plasma are accelerated by the high frequency bias applied to the sample by 1 kV to 50 kV (preferably 2 kV to 20 kV) in the thickness direction of every portion of the sheath, as shown by the arrows in FIG. 3b illustrating step Ka, and the ions collide substantially perpendicularly against the whole exposed surface of the sample including the side and bottom walls of the trench portion 113 and plug portion 112.

As a result, the rare gas/carbon/hydrocarbon ions penetrate the surface of the sample to a depth of approximately 3 nm to 50 nm, and together with the local heating effect created by the acceleration energy of the ions, the surface material of the sample and the ions combine/blend or react efficiently, and a carbonized layer 122 mainly composed of C—C coupling(diamond like carbon, hereinafter called DLC) coupled in a strong Sp3 hybrid orbital manner, Si—C coupling, or C—H coupling, is created on the exposed surface of the sample or to a depth of 3 nm-50 nm (preferably 5 nm-30 nm) of the exposed surface.

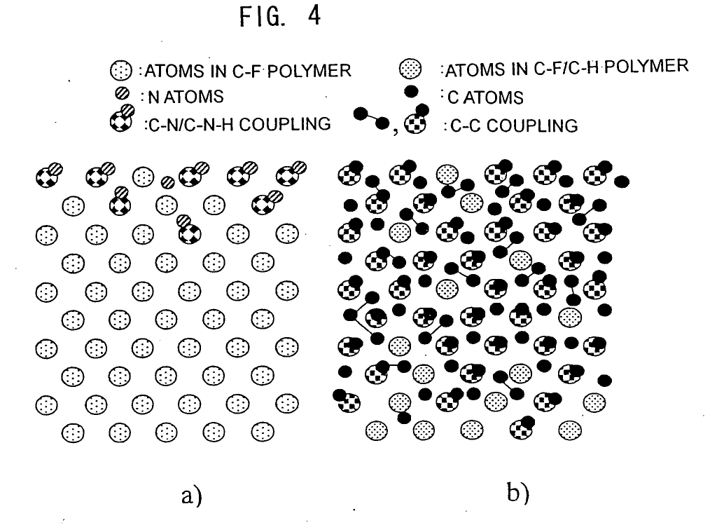

The explanatory view showing the application of the present invention to a low-k material composed of C—F and C—H couplings is shown in FIG. 4b in correspondence to FIG. 4a showing the prior art example. The Sp3 hybrid orbital bonding is advanced by the bonding of the introduced C and C—H with the low-k material, and further, C—C coupling of the introduced C and C—H in Sp3 hybrid or bital manner is also advanced, thus the barrier against copper is improved. Since the carbon layer itself includes incomplete carbonized areas, in order to provide complete barrier performance, according to the prior art, the carbonized layer must have at least several dozen atom layers. By reducing the incompleteness of the carbonized layer and by advancing the Sp3 hybrid orbital bonding, the penetration depth of carbon can be reduced to around or a little over ten atom layers.

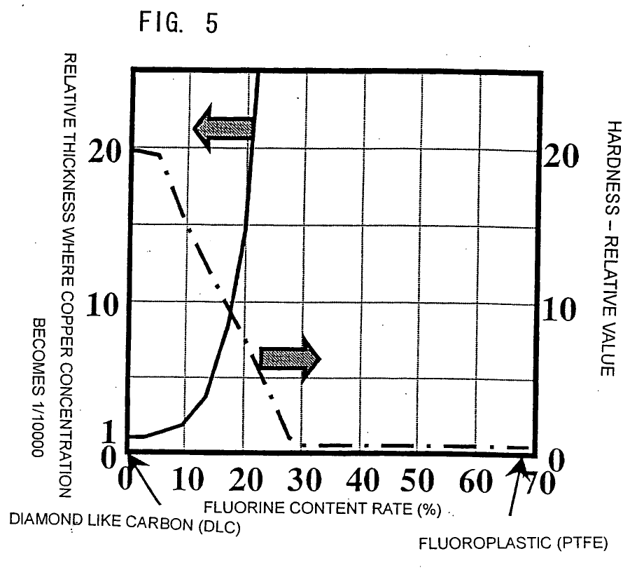

As disclosed for example in the pamphlet of International Publication No. 01/40537, the hardness of the insulator composed of C—F and C—H couplings is reduced as the fluorine content rate (weight %) increases (illustrated by the dashed line of FIG. 5). On the other hand, the film thickness of the insulator required to reduce the copper concentration to one-ten thousandth rapidly increases as the fluorine content rate increases (illustrated by the solid line of FIG. 5). At the point where the fluorine rate equals zero, a state close to diamond like carbon or DLC is observed where C—C coupling of hard Sp3 hybrid orbital bonding is dominant. On the other hand, in the areas where the fluorine rate is over 30 (weight %), C—C coupling of a soft Sp2 hybrid orbital bonding is dominant.

By implanting C and C—H atoms/molecules, fluorine bonds with hydrogen and turns into hydrogen fluoride gas which is then evacuated, while the concentration of carbon increases, so as a result, the fluorine content rate is reduced and the C—C coupling of hard Sp3 hybrid orbital is increased, thus strengthening the barrier function with a thinner film thickness.

Further, by adding 1 to 5% of CO gas or CO2 gas to the process gas, the hydrogen inside the DLC is eliminated, so the C—C coupling is strengthened even further and the barrier performance is improved.

By the carbonizing process increasing the C—C coupling of Sp3 hybrid orbital, the dielectric constant of the insulator increases (for example, Japanese Patent Laid-Open Publication No. 11-297686). However, according to the present invention, carbonization is performed to a depth reaching 3-50 nm (preferably 5-30 nm) from the exposed surface of the low-k material, and the ratio of this carbonized area within the whole volume of the low-k material is so little that the capacity between wirings is not increased much by this carbonization process.

By this carbonization, a barrier layer is created between the low-k material and the conductive material. This barrier layer is created not by depositing a film over the side and bottom sides of the trench 113 and plug 112, but by reforming the surface of the original low-k material, advantageously according to which the dimension for filling in the conductive material is not varied by the step Ka of FIG. 3b. This carbonized layer does not show good compatibility with copper as the conductive material.

The compatibility with copper is improved greatly and copper is implanted uniformly by performing a plasma process (to a depth of 1 nm or less) utilizing hydrogen dominant gas or gas including silicon such as monosilane (SiH₄) or disilane (Si₂H₆), and utilizing ion acceleration voltage of less than 1 kV as bias voltage, to make hydrogen ions, silicon ions or silicon hydroxide ions collide against the exposed surface of the present carbonized layer. Moreover, by the collision of high energy ions, the accelerated particles penetrate into the cavity portion of the low-k material, and by the energy of the accelerated particles the low-k material atoms near the surface of the material or the C and CH components deposited on the exposed surface of the low-k material are hammered into the interior of the material, increasing the density near the surface and strengthening the bond between the atoms of the carbonized layer, and thereby improving the barrier performance.

Moreover, if conductive material exists on the exposed surface of the sample during the process of FIG. 3b, the conductive material is sputtered notably by the collision of accelerated high energy ions, by which the conductive material surface becomes rough or the other areas damaged. Therefore, during the process of FIG. 3b, it is essential that the conductive material 101 be covered by the insulating film 102 above the lower layer wiring.

The means of plasma generation is not limited to the-one shown in FIG. 2, and can also be a parallel-plate type or a microwave application type means.

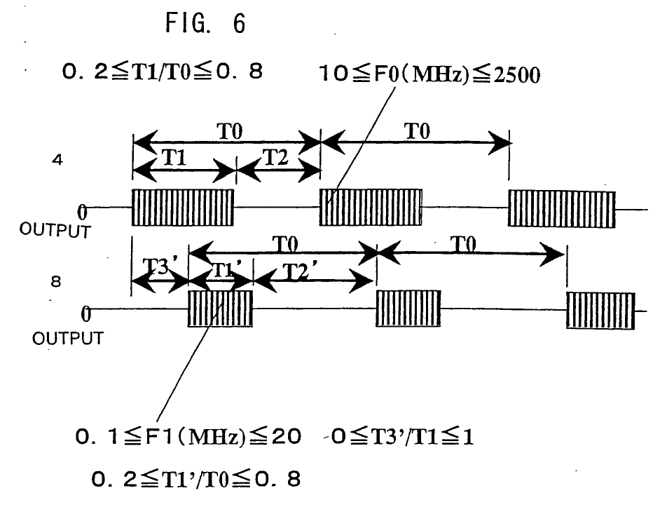

The plasma tends to become unstable when the pressure within the processing chamber is increased, so in that case, it is desirable to generate plasma intermittently as shown in FIG. 6. After outputting high frequency from the plasma generating HF source 4 for a predetermined period of time (T1) (illustrated in the upper step of FIG. 6), the high frequency output is reduced to either zero or a very small value for a predetermined time (T2), and then the high frequency output is resumed again. The repeating period of output (T0) from the plasma generating high frequency source 4 is between 1 μs to 1 ms (preferably between 10 μs and 100 μs),and the duty (T1/T0) during the period of output of the high frequency power is 10% to 80%, preferably 20% to 50%.

When performing intermittent plasma generation, the bias applying high frequency power supply 8 also outputs high frequency being amplitude-modulated in pulse state (FIG. 6 lower step). The output timing of the pulse from the bias applying high frequency power supply 8 is delayed by T3′ from the pulse of the plasma generating high frequency source 4, preferably so that it is output around the last half of the pulse (T1) from the plasma generating high frequency source 4 when the plasma density is high or just after the pulse has been turned off.

During period T3′, products from components C or CH or radicals generated by discharge is adhered on the surface. By irradiating rare gas/carbon/hydrocarbon ions accelerated by the bias high frequency power supply 8 after these products etc. are adhered to the surface, the low-k material surface is efficiently reformed (carbonized), and a carbon dominant layer 12 or a compound layer of low-k material and carbon is created to reach a depth of approximately 2 nm to 50 nm from the surface of the low-k material.

By maintaining the surface temperature of the sample to within 300 to 450 degrees which is below the resisting temperature of the low-k material, the coupling between the low-k material and carbon is accelerated. When the surface reforming process of the low-k material shown in FIG. 3(b) is completed, the sample 7 is transferred in vacuum via the vacuum transfer chamber 153 to an etching chamber of one of the processing chambers 151, where the insulating film 102 above the lower layer wiring is penetrated by plasma etching as shown in FIG. 3c, and unnecessary deposits are removed by plasma cleaning. Further, the plasma etching/cleaning process (step L′) of FIG. 3c can be performed according to a normal etching/cleaning process condition with a pressure range of 0.1 Pa to 100 Pa. However, at the time the conductive material is exposed, the bias voltage applied to the sample is set to 0.5 kV or lower (preferably 0.2 kV or lower, or no application at all) so as to prevent sputtering of the conductive material, performing a radial-dominant process or a process utilizing radicals and weakly accelerated ions.

When the penetration process of the insulating film 102 above the lower layer wiring is completed, the sample travels through the vacuum transfer chamber 153, the lock chamber 155 and the atmosphere robot 157, and is stored in the FOUP 158A or 158B. The FOUP 158A or 158B is then transferred by the inter-apparatus atmospheric transfer device to a film forming apparatus, where a process (step N) of filling copper 115 as conductor material to the sample is performed (FIG. 3d). Thereafter, the sample is stored again in the FOUP, which is then transferred by the inter-apparatus atmospheric transfer device to a CMP apparatus, where the sample goes through a smoothing process (step O, FIG. 3e).

Further, if the plasma etching/cleaning process (step L′) is performed by the film forming apparatus of FIG. 3c, the oxidation of the exposed surface of copper under atmospheric pressure is prevented, so the performance of the integrated circuit is advantageously improved. Moreover, if the system enables the sample to be transferred in vacuum consistently from the etching apparatus, the surface reforming chamber 1 to the film forming apparatus, the drawback caused by the atmospheric transfer between the etching device and the film forming apparatus is solved.

According to the present invention, since the barrier forming process is completed by the surface reforming process of the low-k material within the etching apparatus, and there is no need to create a barrier metal layer, the diameter of the copper embedded in the plug portion can be as wide as the etching dimension of the low-k material. Thus, compared to the prior art device, the resist of the copper wiring portion is reduced, and the delay of signals within the integrated circuit with high integration is advantageously reduced, so therefore, fabrication of highly integrated and high speed integrated circuit is enabled.

Moreover, since the surface reforming process providing barrier and surface protection to the surface is completed before the sample is transferred via atmospheric pressure region to the film forming apparatus, the deterioration of the exposed surface of low-k material caused by moisture, oxygen etc. within the atmosphere is prevented, and a multilevel interconnection with improved reliability can be realized.

Similarly, if a nitriding process is to be performed as barrier process or surface protecting process, the effects similar to those mentioned above can be achieved by utilizing mixed gas including nitrogen gas or ammonias containing much nitrogen and rare gas such as helium, argon and xenon, and further utilizing the plasma generating means and bias application means to the stage similar to those mentioned above.

When utilizing nitriding gas with carbonizing gas or boride-forming gas, a CN-forming or BN-forming process can be performed. According to the property of the low-k material, the process appropriate for providing barrier or surface protection utilizing plasma is selected and used from the following surface reforming processes, which include carbonizing process, nitride process, brominating process, boride-forming process, reduction process, amorphous-forming process, or a combination thereof.

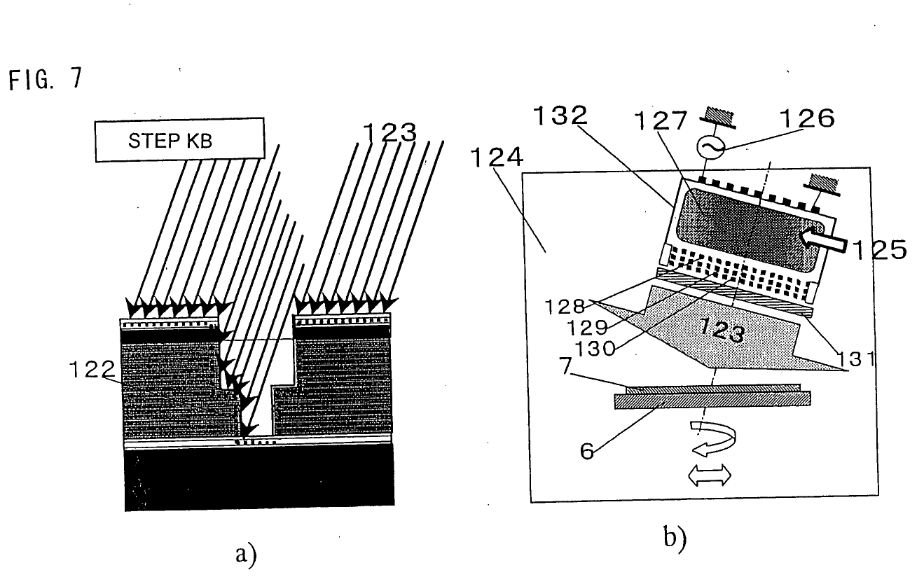

FIGS. 7a and 7b are used to explain another embodiment of the present invention. The processes illustrated from FIG. 10A to FIG. 10K are the same as the prior art. A sample 7 having been completed the process shown in FIG. 10K is transferred in vacuum via the vacuum transfer chamber 153 shown in FIG. 1 to a large-area accelerated beam processing chamber 124 illustrated in FIG. 7b which is one of the processing chambers 151. There, the sample is mounted on a stage 6. In the present processing chamber, ions of carbon, hydrocarbon, argon and the like accelerated by a power of 1 kV to 50 kV (preferably 2 kV to 20 kV) are diselectrified, and are irradiated as large-area accelerated particle beam 123 to the surface of sample 7 from an oblique direction (FIG. 7a, step KB).

Together with the local heating effect by the acceleration energy of the hydrocarbon and argon particles, the surface material of trench portions 113 and plug portions 112 at the exposed sample surface combine/blend or react efficiently with the particles, forming a carbonized layer 122 to reach a depth of 3 nm-50 nm (preferably 5 nm-30 nm) from the exposed sample surface. By this carbonization, a barrier layer is formed between the low-k material and the conductive material. This barrier layer is not formed by adhering an additive film to the trenches 113 and plugs 112, but by reforming the surface of the original low-k material. Therefore, the present process is advantageous in that the dimension for filling the conductive material is substantially unchanged by step KB of FIG. 7a.

Furthermore, by rotating the stage 9 on which the sample 7 is mounted during the present process (when the diameter of the large-area accelerated particle beam 123 is smaller than the diameter of sample 7, parallel movement should be added to the rotation), the exposed surface of the low-k material is carbonized evenly.

FIG. 7b shows one example of a large-area particle beam output apparatus 132. The beam output apparatus 132 comprises an RF power supply 126 for ion source, a plasma generation unit 127, extraction electrodes 128-130, and a charge-removing cascade shower 131.

In the plasma generation unit 127, inflow gas 125 such as argon/hydrocarbon gas is changed into plasma by the ion-source RF power supply 126 connected to a coil antenna, generating high-density argon/carbon/hydrocarbon ions. A portion of the ions in the plasma generation unit 127 is taken out by a plasma grid electrode 128, then accelerated by a voltage of 1 kV to 50 kV (preferably 2 kV to 20 kV) between the plasma grid electrode 128 and an acceleration electrode 129, before being output from a ground electrode 130 and passed through the cascade shower 131 so as to cause collision of the large-area accelerated particle beam 123 to the sample 7 mounted on the stage 6.

The evacuation of the plasma generation unit 127 should be controlled separately from the evacuation of the whole large-area particle beam output apparatus 132, since their degree of vacuum differ.

If the sample 7 completes the etching process of FIG. 10K with a thin film including carbon deposited on the surface thereof before being transferred in vacuum to the large-area accelerated beam processing chamber 124 to be subjected to the above-explained process, the surface of the low-k material is reformed in a more efficient manner.

The method of generating plasma in the large-area particle beam output apparatus 131 is not limited to the one explained above, and can utilize other means such as microwaves. The number of extraction electrodes or the arrangement thereof is not limited to those illustrated in FIG. 7b.

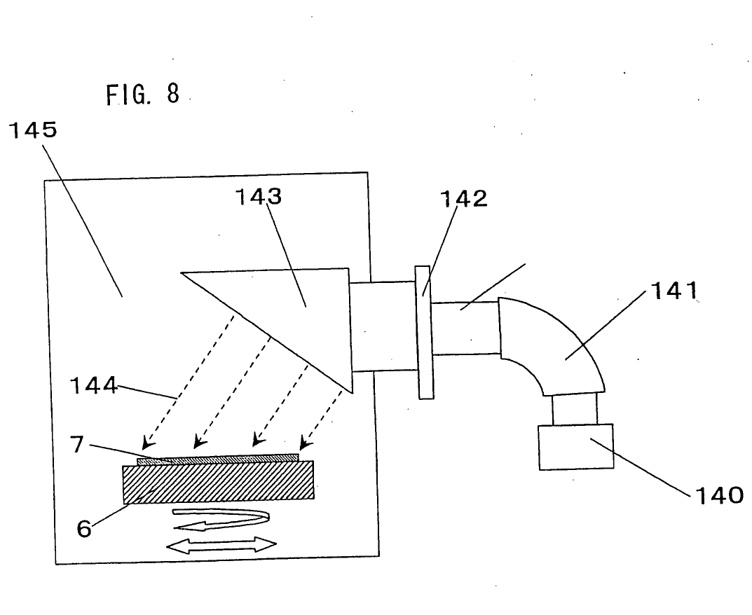

FIG. 8 is used to illustrate an example of an apparatus for executing method (3) explained in the Summary of the Invention. This apparatus comprises an ion source 140, a mass spectrograph unit 141, an acceleration-deceleration unit 142, and an angle adjuster 143.

In the ion source 140, hydrocarbon gas is ionized to take out ion beams of carbon, hydrocarbon or hydrogen. In the mass spectrograph unit 141, only the desired hydrocarbon ions are selected, which are then accelerated at the acceleration-deceleration unit 142 to 1 kV-50 kV (preferably 2 kV-20 kV), passed through the angle adjuster 143 to become a parallel beam 144, and the generated hydrocarbon beam 123 is projected onto the sample 7 mounted in a high vacuum processing chamber 145 from an oblique direction.

By adding rotation and parallel movement to the stage 6 on which the sample 7 is mounted, the hydrocarbon beam can be projected evenly onto the whole exposed sample surface even when the cross-section of the beam 144 is smaller than sample 7.

Together with the local heating effect created by the acceleration energy of the hydrocarbon and argon particles, the surface material of the trench portions 113 and plug portions 112 of the exposed sample surface combine/blend or react efficiently with the particles, and a carbonized layer 122 is created either on the sample surface or to a depth of 3 nm-50 nm (preferably 5 nm-30 nm) of the exposed surface. Though not shown, a charge-removing cascade shower is equipped between the angle adjuster 144 and sample 7 so as to uncharge the introduced ions.

After executing the above carbonization process, the setting of the mass spectrograph unit 141 can be changed to take out hydrogen ions, silicon ions or silicon hydroxide ions, which are accelerated weakly at the acceleration-deceleration unit 142 by 1 kV or lower (preferably 0.5 kV or lower), then passed through the angle adjuster 143 and the charge-removing cascade shower, so that the generated hydrogen, silicon or silicon hydroxide beam 144 is obliquely projected onto the sample 7. Thus, the compatibility with copper is greatly improved at the trench portions 113 and plug portions 112 of the exposed sample surface, and copper can be filled in very evenly.

The above description discloses an example where accelerated particles are used to form a transmutation layer around the surface of the sample to thereby provide a barrier preventing metal ions such as copper ions from penetrating the surface of the sample. However, the applicable range of the present invention is not limited to such example, and the same advantageous effects of the present invention can be achieved if a transmutation layer functioning as barrier can be formed around the surface of the sample by some other process.

One possible method for forming the transmutation layer includes depositing on the surface of the sample a film containing a rich amount of carbon, nitrogen or boron etc., and then heating the sample at a temperature not exceeding 500 degrees (preferably below 450 degrees). By heating, the components including carbon, nitrogen or boron contained in the deposited film penetrates into the low-k film disposed below, by which a transmutation layer having a thickness of approximately 2 nm or more is formed. The variety of the deposited film or the variety of the transmutation layer can be determined and changed according to the material of the base, similar to the above-mentioned embodiment where accelerated particles are used to create the transmutation layer.

It is important that after the heating process, a plasma etching or ashing treatment is performed to reduce the deposited film thickness to less than 5 nm, if very fine processing is performed to the sample.

Another possible method for forming the transmutation layer includes depositing a film on the surface of the sample, reducing the thickness of the deposited film to about 5 nm or smaller, then heating the sample at a temperature not exceeding 500 degrees (preferably below 450 degrees). After the heating process, accelerated particles can be utilized to perform implantation to the surface of the deposited film so as to accelerate the transmutation of the base material surface.

In the high vacuum processing chamber 145, the sample must be placed in a high-vacuum atmosphere of approximately 10⁻⁶ Pa or lower. However, if the high vacuum processing chamber 145 is connected via a single gate valve 152 and the like shown in FIG. 1 to the vacuum transfer chamber 153 of the multi-chamber to which etching chambers and the like are connected, there is fear that the high vacuum processing chamber 145 may be contaminated during transfer of the sample since the degree of vacuum of the vacuum transfer chamber 153 is significantly degraded than the degree of vacuum of the high vacuum processing chamber 145.

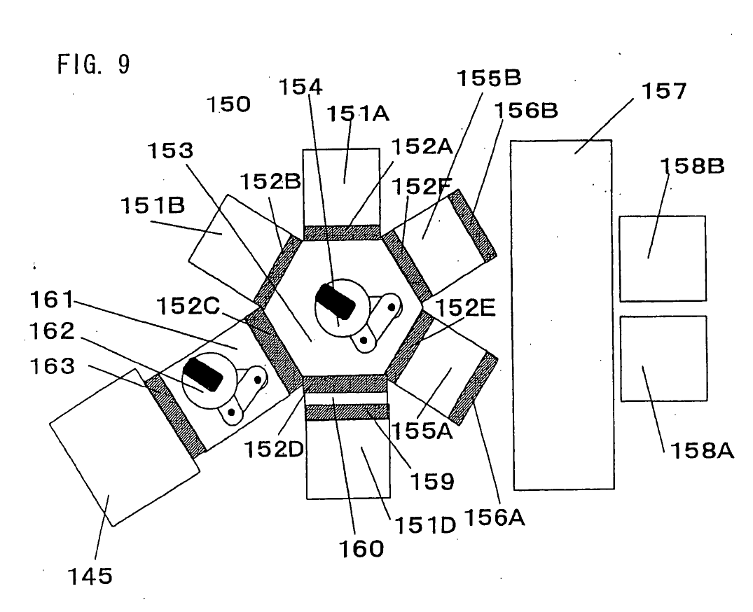

In order to prevent contamination, as shown in FIG. 9, a high vacuum buffer chamber 161 having two gate valves, a vacuum transfer chamber-side gate valve 152C and a high vacuum chamber-side gate valve 163, is provided between the high vacuum processing chamber 145 and the multi-chamber vacuum transfer chamber 153.

When transferring the sample from the multi-chamber vacuum transfer chamber 153 to the high vacuum processing chamber 145, the sample is at first transferred into the high vacuum buffer chamber 161, and then the both gate valves 152c and 163 are closed, before performing high vacuum evacuation of the chamber using an evacuation apparatus that is different from the vacuum transfer chamber evacuation apparatus. By providing the high vacuum buffer chamber 161, it is necessary to further provide a transfer robot 162 in the high vacuum buffer chamber 161 or the high vacuum processing chamber 145 or in between the two chambers for transferring the sample. According to this configuration, contamination is prevented when vacuum-transferring the sample between the vacuum transfer chamber 153 and the high vacuum processing chamber 145.

According to another example, the contamination caused by transferring the sample between the vacuum transfer chamber 153 and the high vacuum processing chamber 145 can be reduced greatly by providing a high vacuum evacuation portion 160 having a narrow vertical width through which the arm of the evacuation robot 154 supporting the sample can pass, and by evacuating the high vacuum evacuation portion 160 from the upper and lower portions of the evacuation portion 160 at least before, during and after the gate valve 152D between the vacuum transfer chamber 153 and high vacuum processing chamber 145 is opened.

By reducing the length of the high vacuum evacuation portion 160 in the wafer transfer direction so that the arm of the vacuum robot 154 can access the sample mounted on the stage in the high vacuum processing chamber 145, there will be no need for an additional transfer apparatus.

It is also possible to reduce the contamination caused by the transfer of the sample between the vacuum robot 153 and the high vacuum processing chamber 145 by providing to the high vacuum evacuation portion 160 an inlet through which clean rare gas or nitrogen gas is introduced and an evacuation opening enabling the chamber to be evacuated to high vacuum, and performing high vacuum evacuation of the evacuation portion 160 at least before, during and after the opening of the gate valve 152D while providing clean air from above and below the high vacuum evacuation portion 160.

According to the present embodiment, a multilevel interconnection utilizing a low-k material can be realized reliably without increasing the wiring resist of copper.

The present invention offers a method and apparatus for performing are forming process of the exposed surface of a low-k material which has been machined for damascene in a system comprising an etching apparatus or a system comprising an etching apparatus and an exposed surface reforming apparatus connected to the etching apparatus via vacuum transfer. The reforming process provides barrier and surface protection to the exposed surface, so there is no need to provide a barrier metal layer according to the invention. Thus, the diameter of copper filled in the plug portion is as wide as the exposed dimension of the low-k material after etching. Therefore, the resistance of the copper wiring is reduced compared to the prior art configuration. Further, since the surface reforming process adding barrier and surface protection to the sample is completed before transferring the sample to the film forming apparatus via the atmospheric pressure region, the alteration of the exposed low-k material surface by moisture and oxygen in the atmosphere is prevented, and the multilevel interconnection being achieved is highly reliable.

What is claimed is:

1. A method for forming a conductive damascene structure by filling copper in a plug portion formed on an insulating film, the method comprising:
after etching a low-k material, providing a copper barrier treatment to an etched surface of the low-k material by a surface reforming process performed to carbonize, nitride, bromize, form into boride, reduce, or form into amorphous the etched surface, or a combination thereof; the surface reforming process being performed by making ions accelerated by voltage or neutral particles obtained by diselectrifying the accelerated ions collide against the etched surface in either a same processing chamber as where the low-k material was etched or in a different processing chamber after being transferred thereto in vacuum; and then filling copper in the plug portion having the etched surface provided with the copper barrier treatment.

2. A method for forming a damascene structure according to claim 1, wherein a surface reforming material is deposited on the etched surface before making said accelerated ions or said neutral particles obtained by diselectrifying said accelerated ions collide against the etched surface.

3. A method for forming a damascene structure according to claim 1, wherein the ions are accelerated by a voltage in the range of 1 keV to 50 keV.

4. A method for forming a conductive damascene structure by filling copper in a plug portion formed on an insulating film, the method comprising:
prior to filling copper in the plug portion, forming the plug portion by a film forming process and an etching process that provide either little or no copper barrier property to side wall portions and plane portions defining inner walls of the plug portion, and then forming at once a copper barrier layer on the side wall portions and the plane portions of the created plug portion by a plasma process utilizing a gas plasma including a component that functions as a barrier against copper.

5. A method for forming a conductive damascene structure by filling copper in a plug portion formed on an insulating film, the method comprising:
prior to filling copper in the plug portion formed to have on its inner wall a two-step trench portion comprising a large cross-section and a small cross-section via a plane portion, forming the plug portion by a film forming process and an etching process that provide either little or no copper barrier property to side wall portions and the plane portions defining the inner walls of the plug portion, and then forming at once a copper barrier layer on the side wall portions and the plane portions of the created plug portion having little or no copper barrier property by a plasma process utilizing a gas plasma including a component that functions as a barrier against copper.

6. A method for forming a conductive damascene structure by filling copper in a plug portion formed on an insulating film, the method comprising:
prior to filling copper in the plug portion, forming the plug portion by a film forming process and an etching process that provide either little or no copper barrier property to side wall portions and plane portions defining inner walls of the plug portion, and then forming at once a copper barrier layer on the side wall portions and the plane portions of the created plug portion by a plasma process utilizing a gas plasma generated from a mixture including at least a rare gas and one of the following gases; carbon atom-containing gas, nitrogen atom-containing gas, hydrogen atom-containing gas, bromine atom-containing gas, or boron atom-containing gas.

7. A method for forming a conductive damascene structure by filling copper in a plug portion formed on an insulating film, the method comprising:
prior to filling copper in the plug portion formed to have on its inner walls a two-step trench portion comprising a large cross-section and a small cross-section via a plane portion, forming the plug portion by a film forming process and an etching process that provide either little or no copper barrier property to side wall portions and plane portions constituting the inner walls of the plug portion, and then forming at once a copper barrier layer on the side wall portions and the plane portions of the created plug portion by a plasma process utilizing a gas plasma generated from a mixture of rare gas and hydrocarbon gases.

8. A method for forming a damascene structure according to claim 4, wherein the copper barrier layer is formed to reach a depth of 3 nm to 50 nm.

9. A method for forming a damascene structure according to claim 5, wherein the copper barrier layer is formed to reach a depth of 3 nm to 50 nm.

10. A method for forming a damascene structure according to claim 6, wherein the copper barrier layer is formed to reach a depth of 3 nm to 50 nm.

11. A method for forming a damascene structure according to claim 7, wherein the copper barrier layer is formed to reach a depth of 3 nm to 50 nm.

12. A method for forming a conductive damascene structure by filling copper in a plug portion formed on an insulating film, the method comprising:
prior to filling copper in the plug portion, forming the plug portion by a film forming process and an etching process that provide either little or no copper barrier property to side wall portions and plane portions defining inner walls of the plug portion, and then forming at once a copper barrier layer on the created plug portion by turning gas including at least carbon atom-containing gas, nitrogen atom-containing gas, hydrogen atom-containing gas, bromine atom-containing gas, or boron atom-containing gas into plasma so as to generate ions including said component; accelerating the generated ions by 1 keV to 50 keV; and making the accelerated ions collide against both the side wall portions and the plane portions of the formed plug portion to create the copper barrier layer.

13. A method for forming a damascene structure according to claim 12, wherein the processing of gas into plasma and the colliding of particles against both the side wall portions and the plane portions of the plug portion are performed in atmospheric pressure or greater pressure.

14. A method for forming a damascene structure according to claim 12, wherein the processing of gas into plasma and the colliding of particles against both the side wall portions and the plane portions of the plug portion are performed in different depressurized conditions.

15. A method for forming a damascene structure according to claim 12, wherein after the etching process is completed, a sample being etched is transferred under depressurized condition to be subjected to the particle collision process.
